(19) United States
(12) Patent Application Publication
(10) Pub. No.: US 2026/0040655 A1
(43) Pub. Date: Feb. 5, 2026

(54) SEMICONDUCTOR DEVICE AND MANUFACTURING METHOD THEREOF

(71) Applicant: Hon Young Semiconductor Corporation, Hsinchu City (TW)

(72) Inventor: Jian-Yi WU, Hsinchu City (TW)

(21) Appl. No.: 18/902,961

(22) Filed: Oct. 1, 2024

(30) Foreign Application Priority Data
Jul. 31, 2024 (TW) 113128447

(51) Int. Cl. H01L 29/51; H01L 21/04; H01L 29/16; H01L 29/66; H01L 29/78

(52) U.S. Cl. CPC H10D 64/685; H01L 21/049; H10D 12/031; H10D 30/668; H10D 62/8325

(57) ABSTRACT

A method of forming a semiconductor device includes forming a gate oxide layer over an epitaxial layer including a drift region and a source region, forming a first boron-containing layer over the gate oxide layer, performing a thermal process, such that the boron in the first boron-containing layer moves in a direction toward the epitaxial layer to form a second boron-containing layer between the epitaxial layer and the gate oxide layer, and forming a gate over the gate oxide layer.

### CROSS-REFERENCE TO RELATED APPLICATION

This application claims priority to Taiwan Application Serial Number 113128447, filed Jul. 31, 2024, which is herein incorporated by reference in its entirety.

### BACKGROUND

### Technical Field

The present disclosure and some embodiments relate to a semiconductor device and a manufacturing method thereof.

### Description of Related Art

Silicon carbide semiconductor devices are prone to low channel mobility, threshold voltage drift, lack of reliability of a gate oxide layer at high temperatures, and drift of a body diode in the forward conduction state due to the presence of defects in the silicon carbide/silicon oxide interface. Due to the presence of defects in the silicon carbide/silicon oxide interface, the channel migration rate of silicon carbide semiconductor devices is severely limited, and the reliability of the gate oxide layer and the stability of the threshold voltage are also greatly affected. Therefore, there is an urgent need for a manner of alleviating the defects in the silicon carbide/silicon oxide interface to improve the performance of the silicon carbide semiconductor devices.

### SUMMARY

Some embodiments of the present disclosure provide a method of forming a semiconductor device, which includes: forming a gate oxide layer over an epitaxial layer, where the epitaxial layer includes a drift region and a source region; forming a first boron-containing layer over the gate oxide layer; performing a thermal process, such that the boron in the first boron-containing layer moves in a direction toward the epitaxial layer to form a second boron-containing layer between the epitaxial layer and the gate oxide layer; and forming a gate over the gate oxide layer.

In some embodiments, the method further includes: after forming the second boron-containing layer, performing an annealing process in an oxygen-containing environment.

In some embodiments, the process temperature of performing the thermal process is higher than the process temperature of forming the first boron-containing layer.

In some embodiments, before performing the thermal process, the thickness of the first boron-containing layer is less than that of the gate oxide layer.

In some embodiments, before performing the thermal process, the thickness of the first boron-containing layer is 3% to 10% of the thickness of the gate oxide layer.

In some embodiments, after forming the second boron-containing layer, the boron content in the upper surface of the gate oxide layer is less than that in an interface between the gate oxide layer and the second boron-containing layer.

Some embodiments of the present disclosure provide a semiconductor device, which includes: a substrate, an epitaxial layer, a boron-containing layer, a gate dielectric layer, and a gate. The epitaxial layer is disposed on the substrate, and includes a drift region and a source region. The boron-containing layer is disposed on the epitaxial layer. The gate dielectric layer is disposed on the boron-containing layer. The gate is disposed on the gate dielectric layer.

In some embodiments, the thickness of the boron-containing layer is less than that of the gate dielectric layer.

In some embodiments, the boron-containing layer is a boron oxide layer and the gate dielectric layer is a silicon oxide layer.

In some embodiments, the boron content in an upper surface of the gate dielectric layer is less than the boron content in an interface between the gate dielectric layer and the boron-containing layer.

### BRIEF DESCRIPTION OF THE DRAWINGS

FIGS. 1 to 5 are cross-sectional views of a method for manufacturing a semiconductor device in some embodiments of the present disclosure; and

FIG. 6 is a cross-sectional view of a semiconductor device in other embodiments of the present disclosure.

### DETAILED DESCRIPTION

The semiconductor device in some embodiments of the present disclosure is used to alleviate the interfacial defects between a substrate and a gate dielectric layer. Specifically, a boron-containing layer may be formed between the gate dielectric layer and the substrate, and the boron in the boron-containing layer may be used to promote stress relaxation of silicon oxide, thus alleviating the interfacial defects between the substrate and the gate dielectric layer and improving the electron mobility of the semiconductor device.

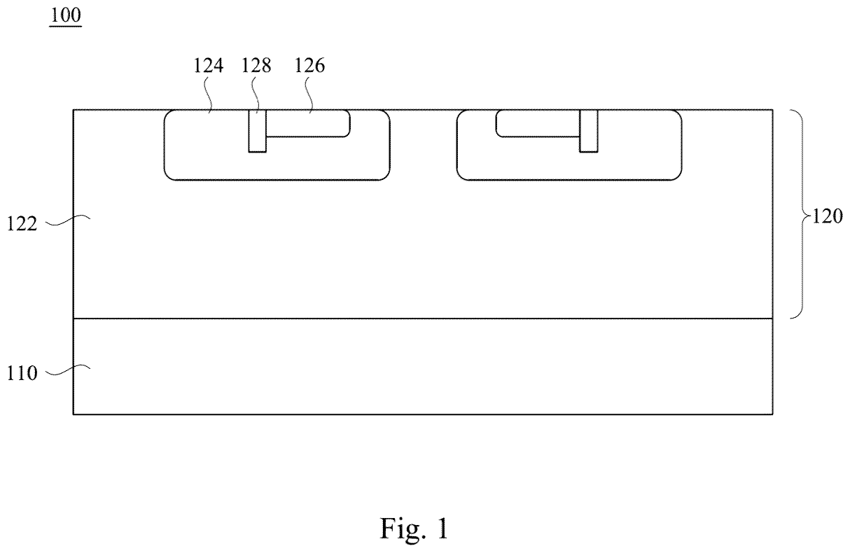

FIGS. 1 to 5 are cross-sectional views of a method for manufacturing a semiconductor device 100 in some embodiments of the present disclosure, where the semiconductor device 100 shown from FIGS. 1 to 5 is a planar semiconductor device. Referring to FIG. 1, an epitaxial layer 120 is formed on a substrate 110, where the epitaxial layer 120 may include a drift region 122, a well region 124, a source region 126, and a body contact region 128. Specifically, the well region 124 is disposed on the drift region 122, the source region 126 and the body contact region 128 are disposed in the well region 124, and the body contact region 128 is disposed adjacent the source region 126. The substrate 110, the drift region 122, and the source region 126 may have a first conductor type, and the well region 124 and the body contact region 128 may have a second conductor type different from the first conductor type. In some embodiments, the first conductor type may be an N type and the second conductor type may be a P type. In some embodiments, the dosage concentration of the substrate 110 and the source region 126 may be higher than that of the drift region 122. The dosage concentration of the body contact region 128 may be higher than that of the well region 124. In some embodiments, the substrate 110 and the epitaxial layer 120 may be made by using semiconductors, such as silicon carbide.

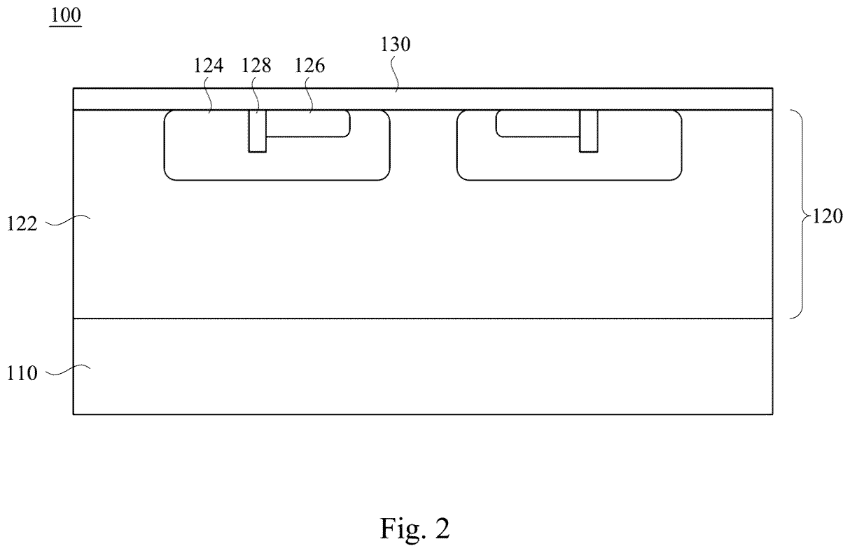

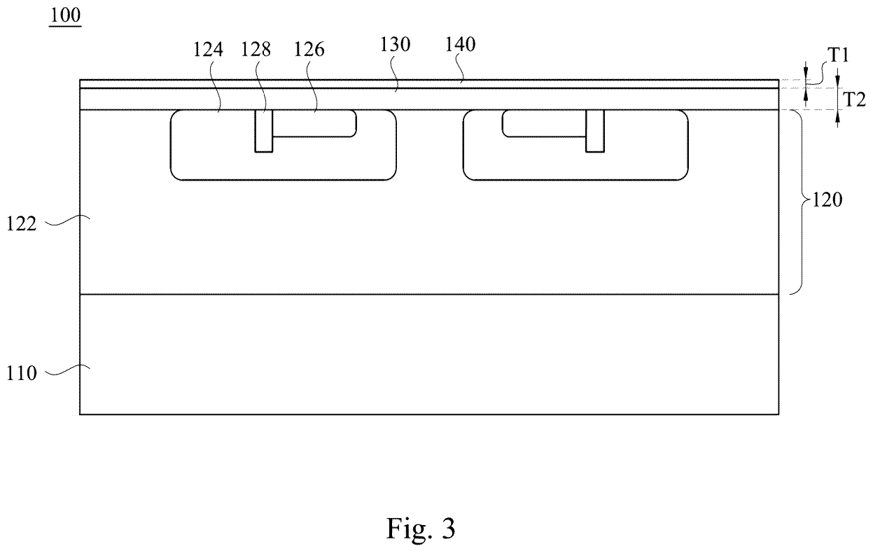

Referring to FIG. 2, a gate oxide layer 130 is formed on the epitaxial layer 120. Specifically, the gate oxide layer 130 may be formed by means of any proper oxidation process. For example, a dry oxidation process may be performed to oxidize the surface of the epitaxial layer 120, to form the gate oxide layer 130 on the epitaxial layer 120. The thickness (the thickness T2 in FIG. 3) of the formed gate oxide layer 130 ranges from about 400 Å to about 500 Å. In some embodiments, the gate oxide layer 130 is made of silicon oxide. During the thermal oxidation process, the silicon atoms on the surface of the epitaxial layer 120 are bonded to the oxygen atoms to release stress and cause body expansion, which leads to interfacial defects between the epitaxial layer 120 and the gate oxide layer 130. Such interfacial defects may lead to reduction of electron mobility of the semiconductor device 100. In some embodiments, before forming the gate oxide layer 130, the surface of the epitaxial layer 120 may be first cleaned.

Referring to FIG. 3, a first boron-containing layer 140 is formed on the gate oxide layer 130. Specifically, the first boron-containing layer 140 may be formed on the gate oxide layer 130 by means of any proper manner such as ion implantation, atomic layer deposition, or chemical vapor deposition. In some embodiments, the first boron-containing layer 140 is a boron oxide layer (B₂O₃). In some embodiments, the first boron-containing layer 140 is formed at a process temperature of about 900° C. to 1000° C. In some embodiments, the thickness T1 of the first boron-containing layer 140 is less than the thickness T2 of the gate oxide layer 130. For example, the thickness T1 of the first boron-containing layer 140 is 3% to 10% of the thickness T2 of the gate oxide layer 130.

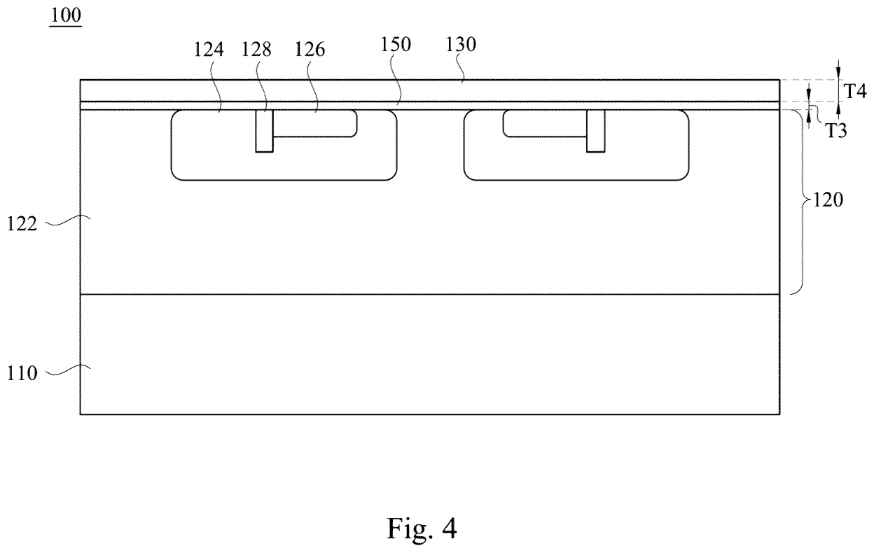

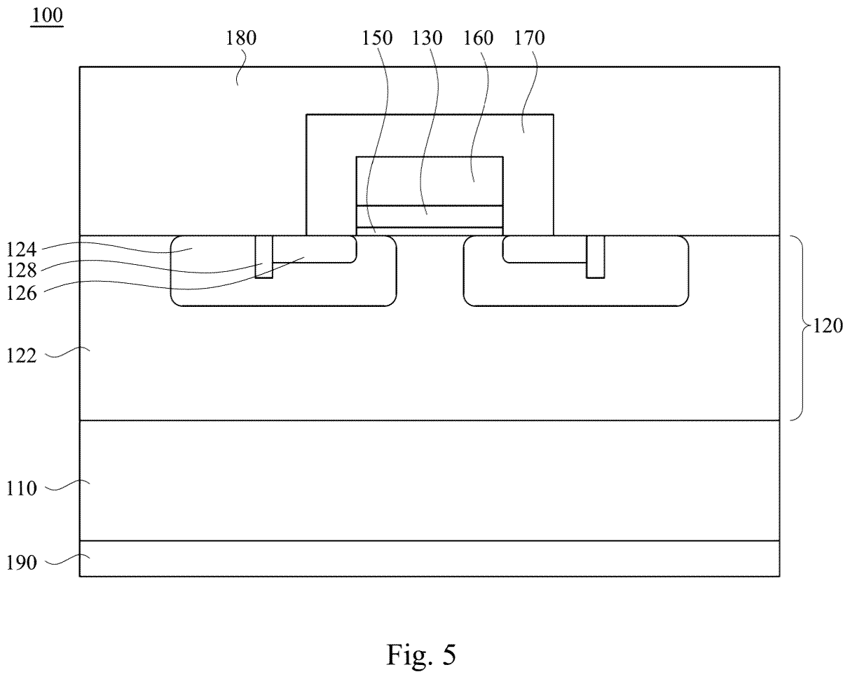

Referring to FIG. 4, a thermal process is performed. The boron in the first boron-containing layer 140 moves towards the epitaxial layer 120, so as to form a second boron-containing layer 150 between the epitaxial layer 120 and the gate oxide layer 130. In some embodiments, the second boron-containing layer 150 is a boron oxide layer (B₂O₃). Specifically, the process temperature of performing the thermal process is higher than that of forming the first boron-containing layer 140. In addition, because the boron atoms has a small atomic radius, the heat of the thermal process can provide a sufficient driving force to move the boron in the first boron-containing layer 140 downward between the epitaxial layer 120 and the gate oxide layer 130. The boron moving downward occupies the positions of the silicon atoms on the surface of the epitaxial layer 120, reducing the bonding strength of the silicon oxide in the gate oxide layer 130 on the surface of the epitaxial layer 120. In this way, stress relaxation of the oxide may be promoted, and interfacial defects between the epitaxial layer 120 and the gate oxide layer 130 may be reduced. The electron mobility of the semiconductor device 100 is also increased accordingly. In some embodiments, the process temperature of performing the thermal process approximately ranges from 1200° C. to 1500° C. The thermal process in FIG. 4 can make most of boron in the first boron-containing layer 140 move downward between the epitaxial layer 120 and the gate oxide layer 130, to form the second boron-containing layer 150. Therefore, after performing the thermal process, the first boron-containing layer 140 no longer exists over the gate oxide layer 130, and the boron content in the upper surface (the interface between the gate oxide layer 130 and the gate 160 in FIG. 5 in the following description) of the gate oxide layer 130 is less than the boron content in the interface between the gate oxide layer 130 and the second boron-containing layer 150. The boron content in the gate oxide layer 130 is also less than that in the second boron-containing layer 150. After forming the second boron-containing layer 150, the thickness T4 of the gate oxide layer 130 approximately ranges from 400 Å to 500 Å. The thickness T3 of the second boron-containing layer 150 is less than the thickness T4 of the gate oxide layer 130. For example, the thickness T3 of the second boron-containing layer 150 is 3% to 10% of the thickness T4 of the gate oxide layer 130. When the thickness T3 of the second boron-containing layer 150 is less than the previous thickness, the boron content between the epitaxial layer 120 and the gate oxide layer 130 is probably insufficient, which accordingly cannot effectively reduce the interfacial defects between the epitaxial layer 120 and the gate oxide layer 130.

After forming the second boron-containing layer 150, a first annealing process is performed in an oxygen-containing environment, so that the boron oxide structure in the second boron-containing layer 150 is densely formed. In some embodiments, during the first annealing process, an inert gas (e.g., argon) may be used as a carrier to carry oxygen, and the ratio of the flow of oxygen to that of the inert gas is not less than 1/9. In some embodiments, during the first annealing process, the ratio of the flow of oxygen to that of the inert gas is between 1/9 and 2/9. In some embodiments, the process temperature of the first annealing process is lower than the process temperature of the thermal process of forming the second boron-containing layer 150. In some embodiments, the process temperature of the first annealing process approximately ranges from 900° C. to 1000° C. When the process temperature of the first annealing process is higher than the foregoing temperature, the gate oxide layer 130 may easily have an electric leakage problem. When the process temperature of the first annealing process is lower than the foregoing temperature, the structure of the boron oxide in the second boron-containing layer 150 may not dense enough, thus failing to effectively alleviate the interfacial defects between the epitaxial layer 120 and the gate oxide layer 130.

After performing the first annealing process, a second annealing process is performed in an environment with nitrogen-containing gas, so as to further alleviate the interfacial defects between the epitaxial layer 120 and the gate oxide layer 130. In some embodiments, the nitrogen-containing gas may be nitrous oxide, nitrous oxide, nitrogen, ammonia or a combination thereof.

Referring to FIG. 5, a gate 160 is formed on the gate oxide layer 130. Specifically, the gate 160, the gate oxide layer 130 and the second boron-containing layer 150 are patterned after forming the gate 160, and therefore, the upper surface of the epitaxial layer 120 is exposed. In some embodiments, the gate 160, the gate oxide layer 130 and the second boron-containing layer 150 may have identical patterns. In some embodiments, the second boron-containing layer 150, the gate oxide layer 130, and the gate 160 may be referred to as a gate structure in combination. Afterwards, a dielectric layer 170 is formed on the epitaxial layer 120, the gate 160, the gate oxide layer 130, and the second boron-containing layer 150. A source electrode 180 in contact with the source region 126 and the body contact region 128 is formed on the dielectric layer 170 and the epitaxial layer 120, and a drain electrode 190 is formed below the substrate 110.

The formed semiconductor device 100 includes the substrate 110, the epitaxial layer 120, the second boron-containing layer 150, the gate oxide layer 130, the gate 160, the dielectric layer 170, the source electrode 180, and the drain electrode 190. The epitaxial layer 120 is disposed on the substrate 110; and includes the drift region 122, the well region 124, the source region 126, and the body contact region 128. The second boron-containing layer 150 is disposed on the epitaxial layer 120. The gate oxide layer 130 is disposed on the second boron-containing layer 150, where the thickness T3 of the second boron-containing layer 150 is less than the thickness T2 of the gate oxide layer 130. The gate 160 is disposed on the gate oxide layer 130. The dielectric layer 170 covers sidewalls of the second boron-containing layer 150, the gate oxide layer 130, and the gate 160 and the upper surface of the gate 160. The source electrode 180 covers the dielectric layer 170 and the epitaxial layer 120, and the source electrode 180 is electrically connected to the source region 126 and the body contact region 128 of the epitaxial layer 120. The dielectric layer 170 electrically isolates the source electrode 180 from the gate 160 and the drain electrode 190 is disposed below the substrate 110. The second boron-containing layer 150 between the gate oxide layer 130 and the epitaxial layer 120 of the present disclosure can be used to alleviate the interfacial defects between the gate oxide layer 130 and the epitaxial layer 120, thus improving the electron mobility of the semiconductor device 100.

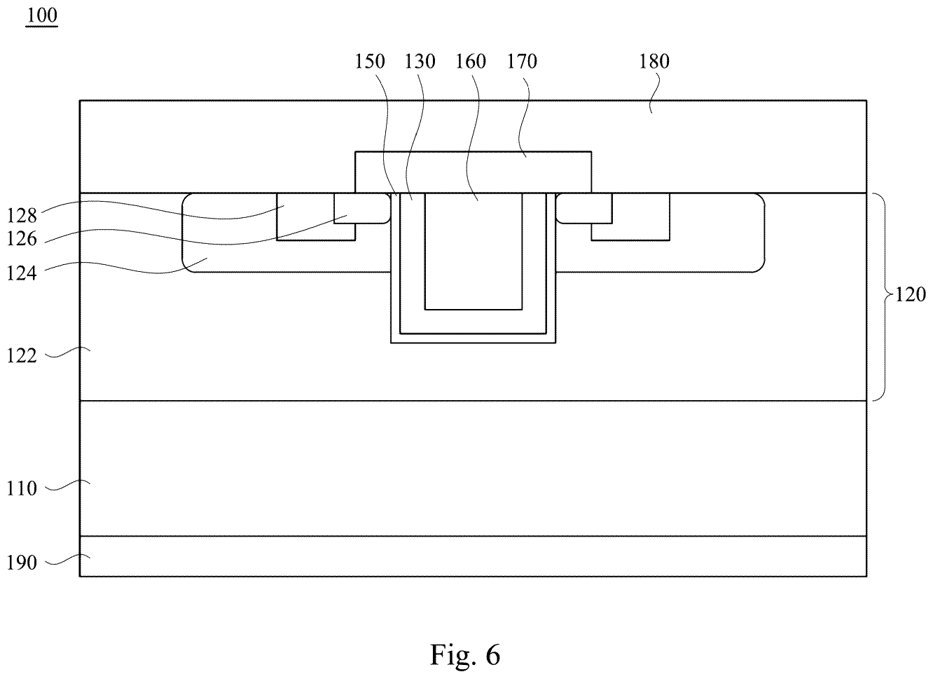

FIG. 6 is a cross-sectional view of a semiconductor device 100 in other embodiments of the present disclosure. The semiconductor device 100 in FIG. 6 differs from the semiconductor device 100 in FIG. 5 in that, the semiconductor device 100 in FIG. 5 is a planar semiconductor device, while the semiconductor device 100 in FIG. 6 is a trenched semiconductor device. The second boron-containing layer 150, the gate oxide layer 130, and the gate 160 in the semiconductor device 100 of FIG. 6 form a trench structure and are formed in the trench of the epitaxial layer 120. The second boron-containing layer 150, the gate oxide layer 130, and the gate 160 are formed between the well regions 124. The gate oxide layer 130 is formed along the bottom and the sidewalls of the gate 160; and the second boron-containing layer 150 is formed along the bottom and the sidewalls of the gate oxide layer 130, and is in contact with the epitaxial layer 120. Refer to the description from FIGS. 1 to 5 for other details of the structure of the semiconductor device 100 in FIG. 6, which are not described herein again.

The method for manufacturing the semiconductor device 100 in FIG. 6 is similar to the method for manufacturing the semiconductor device 100 from FIGS. 1 to 5. Their differences are as follows: During forming of the semiconductor device 100 in FIG. 6, the epitaxial layer 120 has a trench between the well regions 124, and the gate oxide layer 130 and the first boron-containing layer 140 are conformally formed on the epitaxial layer 120. Afterwards, a thermal process is performed, so that the boron in the first boron-containing layer 140 moves towards the epitaxial layer 120, so as to form a second boron-containing layer 150 between the epitaxial layer 120 and the gate oxide layer 130. Then, a gate 160 is formed in the trench of the epitaxial layer 120, and a yellow-light etching process is performed to remove the excess gate 160, the gate oxide layer 130, and the second boron-containing layer 150, such that the top surfaces of the epitaxial layer 120, the gate 160, the gate oxide layer 130, and the second boron-containing layer 150 are coplanar. After performing the yellow-light etching process, the upper surface of the epitaxial layer 120 is exposed. Then, a dielectric layer 170 that covers the gate 160, the gate oxide layer 130, and the second boron-containing layer 150 is formed. A source electrode 180 covering the dielectric layer 170 is formed on the epitaxial layer 120, and a drain electrode 190 is formed below the substrate 110. It should be noted that, the details of forming the gate oxide layer 130, the first boron-containing layer 140, and the second boron-containing layer 150 in FIG. 6 have been discussed in FIGS. 3 and 4, which are not described herein again. Refer to the description from FIGS. 1 to 5 for other details of the manufacturing method of the semiconductor device 100 in FIG. 6, which are not described herein again. The second boron-containing layer 150 between the gate oxide layer 130 and the epitaxial layer 120 in FIG. 6 can be used to alleviate the interfacial defects between the gate oxide layer 130 and the epitaxial layer 120, thus improving the electron mobility of the semiconductor device 100.

It should be noted that, although the present disclosure only illustrates a planar semiconductor device and a trenched semiconductor device having boron-containing layers, the present disclosure is not limited thereto. As long as the boron-containing layer is formed between the gate dielectric layer and the epitaxial layer so as to alleviate the interfacial defects between the epitaxial layer and the gate oxide layer, the structure of the semiconductor device and the manufacturing method thereof all fall within the scope of protection of the present disclosure. For example, the boron-containing layers disclosed herein may also be applicable to other types of semiconductor devices, such as shielded gate trench semiconductor devices and super junction semiconductor devices.

The above merely describes some rather than all of the embodiments of the present disclosure. Any equivalent changes to the technical solutions adopted by the persons of ordinary skill in the art through the reading the present disclosure are covered by the claims of the present disclosure.

What is claimed is:

1. A method for manufacturing a semiconductor device, comprising:
forming a gate oxide layer on an epitaxial layer, the epitaxial layer having a drift region and a source region;
forming a first boron-containing layer on the gate oxide layer;
performing a thermal process such that boron in the first boron-containing layer moves towards the epitaxial layer, so as to form a second boron-containing layer between the epitaxial layer and the gate oxide layer; and
forming a gate on the gate oxide layer.

2. The method of claim 1, further comprising:
after forming the second boron-containing layer, performing an annealing process in an oxygen-containing environment.

3. The method of claim 2, further comprising:
after performing an annealing process in an oxygen-containing environment, performing an annealing process in an environment with a nitrogen-containing gas.

4. The method of claim 1, wherein a process temperature of performing the thermal process is higher than a process temperature of forming the first boron-containing layer.

5. The method of claim 1, wherein before performing the thermal process, a thickness of the first boron-containing layer is less than that of the gate oxide layer.

6. The method of claim 1, wherein before performing the thermal process, a thickness of the first boron-containing layer is 3% to 10% of a thickness of the gate oxide layer.

7. The method of claim 1, wherein after performing the thermal process, a thickness of the second boron-containing layer is less than that of the gate oxide layer.

8. The method of claim 1, wherein after performing the thermal process, a thickness of the second boron-containing layer is 3% to 10% of a thickness of the gate oxide layer.

9. The method of claim 1, wherein after forming the second boron-containing layer, a boron content in an upper surface of the gate oxide layer is less than that in an interface between the gate oxide layer and the second boron-containing layer.

10. The method of claim 1, wherein the epitaxial layer has a trench before forming the gate oxide layer, and the gate oxide layer and the first boron-containing layer are conformally formed on the epitaxial layer.

11. The method of claim 10, wherein after forming the gate, the gate oxide layer is along a bottom and a sidewall of the gate, and the second boron-containing layer is along a bottom and a sidewall of the gate oxide layer.

12. A semiconductor device, comprising:
a substrate;
an epitaxial layer, disposed on the substrate and having a drift region and a source region;
a boron-containing layer, disposed on the epitaxial layer;
a gate dielectric layer, disposed on the boron-containing layer; and
a gate, disposed on the gate dielectric layer.

13. The semiconductor device of claim 12, wherein a thickness of the boron-containing layer is less than that of the gate dielectric layer.

14. The semiconductor device of claim 12, wherein the boron-containing layer is a boron oxide layer and the gate dielectric layer is a silicon oxide layer.

15. The semiconductor device of claim 12, wherein a boron content in an upper surface of the gate dielectric layer is less than the boron content in an interface between the gate dielectric layer and the boron-containing layer.

16. The semiconductor device of claim 12, wherein the gate, the gate dielectric layer and the boron-containing layer have identical patterns.

17. The semiconductor device of claim 12, further comprising:
a dielectric layer covering sidewalls of the boron-containing layer, the gate dielectric layer, and the gate and a upper surface of the gate;
a source electrode covering the dielectric layer and the epitaxial layer; and
a drain electrode disposed below the substrate.

18. The semiconductor device of claim 12, wherein the epitaxial layer has a trench, and the boron-containing layer, the gate dielectric layer, and the gate are in the trench of the epitaxial layer.

19. The semiconductor device of claim 12, wherein the gate dielectric layer is along a bottom and a sidewall of the gate.

20. The semiconductor device of claim 12, wherein the boron-containing layer is along a bottom and a sidewall of the gate dielectric layer.
